(19) United States
(12) Patent Application Publication
(10) Pub. No.: US 2026/0121384 A1
(43) Pub. Date: Apr. 30, 2026

(54) DUAL LASER ASSEMBLY

(71) Applicant: LEONARDO ELECTRONICS US INC., Tucson, AZ (US)

(72) Inventors: Brian CALIVA, Tucson, AZ (US); Steven E. SMITH, Tucson, AZ (US); Kimberly RULE, Tucson, AZ (US); Hieu TRAN, Tucson, AZ (US); Greg PENNINGTON, Tucson, AZ (US); Ryan KENNY, Tucson, AZ (US)

(21) Appl. No.: 19/005,353

(22) Filed: Dec. 30, 2024

Related U.S. Application Data
(60) Provisional application No. 63/616,259, filed on Dec. 29, 2023.

(51) Int. Cl. H01S 5/40; H01S 5/024

(52) U.S. Cl. CPC H01S 5/4087; H01S 5/02469

(57) ABSTRACT

A laser assembly has multiple laser diode assemblies including a first laser diode assembly and a second laser diode assembly. The first laser diode assembly and the second diode assembly are configured to operate independently or simultaneously with one another and are assembled on a single heatsink.

### CROSS REFERENCE TO RELATED APPLICATION

This application claims benefit to U.S. Provisional Patent Application Ser. No. 63/616,259, filed Dec. 29, 2023, entitled “DUAL LASER ASSEMBLY”, the contents of which are incorporated herein in its entirety.

### FIELD OF THE DISCLOSURE

The present disclosure relates generally to laser assemblies, and more particularly, to laser diode bar assemblies.

### BACKGROUND AND SUMMARY

Laser diode bar assemblies are used in a wide variety of industrial, research, medical, and military applications. In use, a plurality of diode bars or chips are mounted on a substrate to provide the multiplied power of the numerous individual diode bars or chips, verses the effect offered by a single laser diode bar or chip. Referring to FIGS. 1A and 1B, a typical exemplary embodiment of a laser diode bar assembly or stack 100 in accordance with the prior art comprises a plurality of laser bars 102 assembled on a heatsink 104. Laser bars 102 are separated from one another by spacers 106.

Electrical terminals 108, 110 are provided on each side of one end of the stack and configured for attachment of electrical wiring. Terminals 108, 110 may comprise screws, solder connections or crimp connections. Terminals 108, 110 serve as positive or anode electrodes. A third and fourth terminals 115, 116 at the far end of the laser bar array 100 serves as negative or cathode electrodes. Wires 118, 120 from a power source (not shown) are attached to terminals 108, 110. Wires 122, 123 are attached to terminal 115, 116 to complete an electric circuit. Also not shown are optics which are conventionally used to manipulate the output beams of the laser diode bars in the assembly.

In use, current supplied form the power source (not shown) travels through the stack shown by arrow 124.

In accordance with the present disclosure, we provide multiple electrically independent laser diode assemblies or laser diode arrays, on a single heatsink. In one embodiment the laser diode array assemblies are configured to operate independently with one another. In another embodiment the laser diode array assemblies are configured to operate together.

In accordance with one embodiment, the individual laser diode array assemblies are configured to pulse in sync with one another. In another embodiment, the laser diode array assemblies are configured to pulse out of phase with one another.

In another embodiment, the laser diode assemblies are configured to run in constant current separately. In another embodiment, the laser diode assemblies are configured to run in constant current together.

In yet another embodiment, the laser diode array assemblies are identical in diode bar size and spacing to one another. In another embodiment, the laser diode array assemblies are different in diode bar size and spacing to one another.

In one embodiment, the individual laser diode array assemblies are configured to operate at the same wavelengths. In another embodiment the laser diode array assemblies are configured to operate at different wavelengths.

In one embodiment, the individual laser diode assemblies are configured with the same laser diode design or structure. In another embodiment the laser diode assemblies are configured with different laser diode designs or structures.

In yet another embodiment, the individual laser diode array assemblies have different numbers of individual laser bars.

In still yet another embodiment, the laser diode array assemblies are offset from one another.

In still yet another embodiment, the laser diode array assemblies are configured to operate in series.

In still yet another embodiment, the laser diode assemblies are configured to operate in parallel.

A feature and advantage of the instant disclosure which results from providing two laser diode array assemblies on a single heatsink is that we can provide a more compact laser diode array assembly having higher power output or different and/or variable power outputs. This laser diode array assembly also provides significant flexibility in other operational performance characteristics like wavelength, operating voltage, operating current, redundancy in a more compact layout.

Another advantage of providing two laser bar assemblies on a single heatsink is that we can maximize efficiency of the power supply.

According to one aspect of the disclosure there is provided a laser assembly comprising multiple laser diode assemblies including a first laser diode assembly and a second laser diode assembly, wherein the first laser diode assembly and the second diode assembly are configured to be operated independently or simultaneously, and are assembled on a single heatsink.

In one embodiment the first laser diode assembly and a second laser diode assembly each contain a same number of laser bars, or contain a different number of bars.

In another embodiment the first laser diode assembly and the second laser diode assembly are configured to run simultaneously.

In a further embodiment the first laser diode assembly and the second laser diode assembly are configured to run independently of one another.

In yet another embodiment the first laser diode assembly and the second laser diode assembly are configured to run in pulse mode or in a constant current mode. In such embodiment the first laser diode assembly and the second laser diode assembly may be configured to run in phase. Alternatively, the first laser diode assembly and the second laser diode assembly may be configured to run out of phase.

In one embodiment the first laser diode assembly and the second laser diode assembly are connected in series.

In another embodiment the first laser diode assembly and the second laser diode assembly are connected in parallel.

In a further embodiment the first laser diode assembly and the second laser diode assembly have different emission spectrums.

In still yet another embodiment the first laser diode assembly and the second laser diode assembly have laser diode bars of different dimensions.

In a further embodiment the first laser diode assembly and the second laser diode assembly have laser diode bars that have different operating characteristics.

In a still further embodiment the first laser diode assembly and the second laser diode assembly have different dimensions.

In another embodiment the first laser diode assembly and the second laser diode assembly are interleaved with one another.

In yet another embodiment the first laser diode assembly and the second laser diode assembly are rotated to one another, and share a common electrode. In such embodiment the first laser assembly and the second laser assembly may share a common cathode.

In still yet another embodiment, the laser assembly further comprises optics for conditioning a beam generated by the laser assembly.

### BRIEF DESCRIPTION OF THE DRAWINGS

Still other features and advantages of the present disclosure will be seen from the following detailed description, taken in conjunction with the accompanying drawings, wherein like numerals depict like parts, and wherein:

FIG. 1A is a perspective view and FIG. 1B is a top plan view of a laser diode array assembly in accordance with the prior art;

FIG. 2A is an end view of a first embodiment of a multiple laser diode array assembly in accordance with the present disclosure on a single heatsink;

FIG. 2B is a top plan view of the laser diode assembly of FIG. 2A;

FIG. 3 is a top plan view of another embodiment of a multiple laser diode assembly of the present disclosure showing multiple laser diode assemblies on a common cathode;

FIG. 4 is a top plan view of yet another embodiment of a multiple laser diode assembly of the present disclosure showing two laser diode assemblies interleaved with one another on a common heatsink; and

FIG. 5 is a top plan view of still yet another embodiment of the present disclosure showing four laser diode assemblies on a common heatsink.

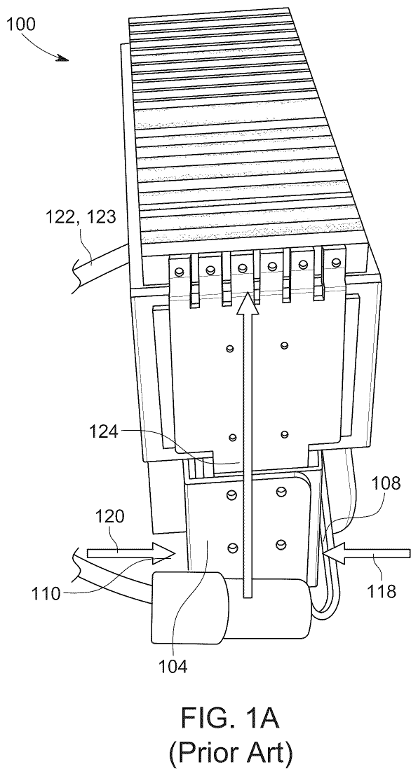

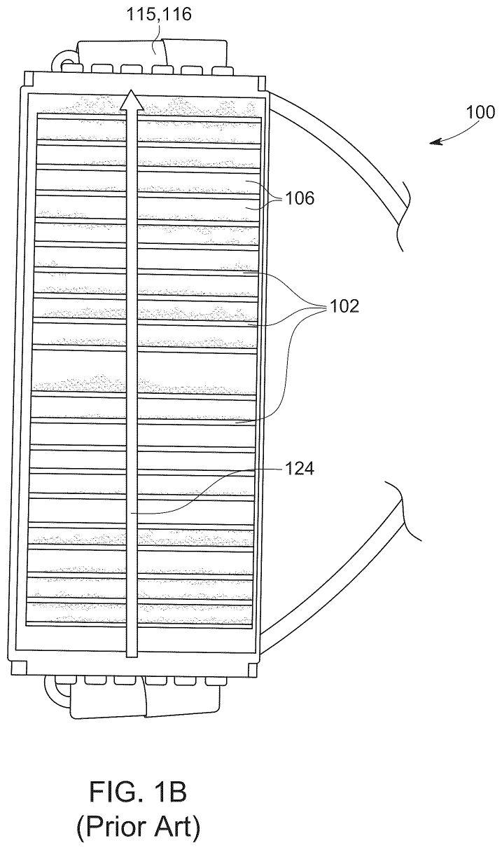

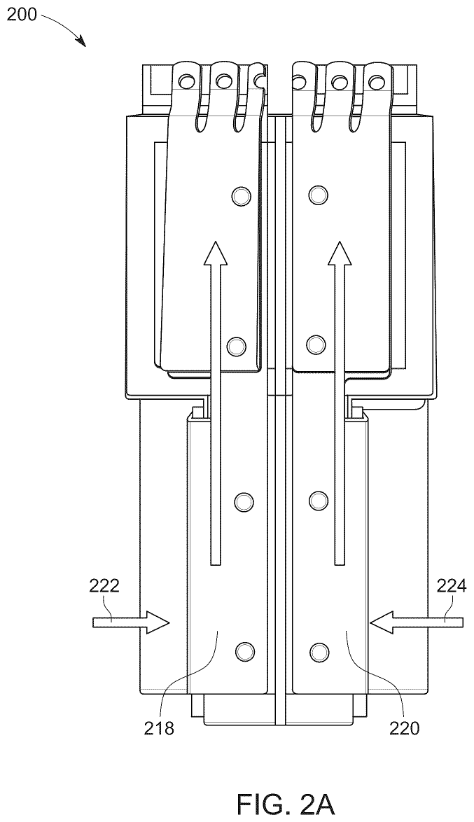

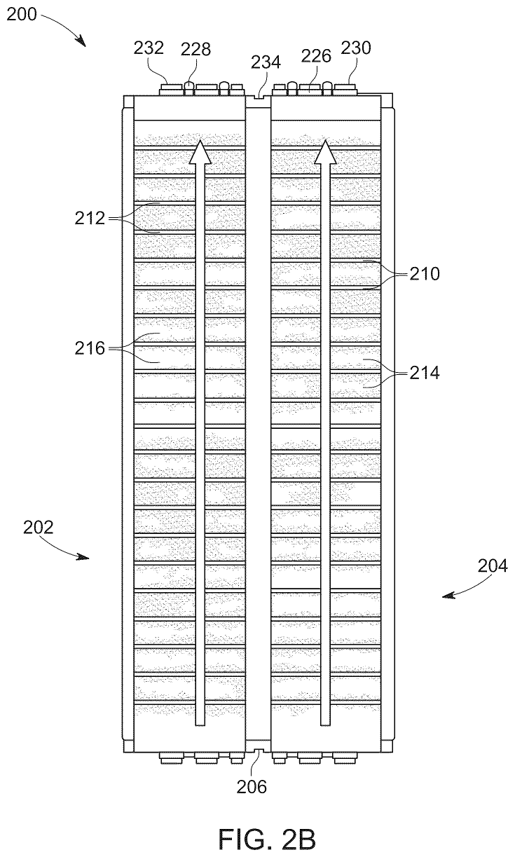

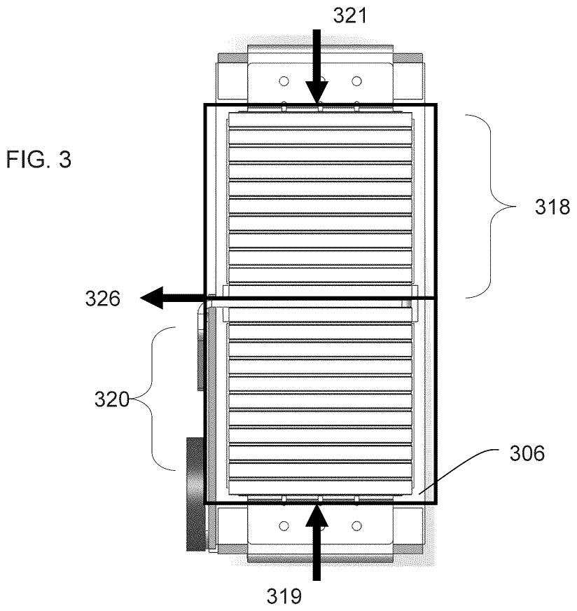

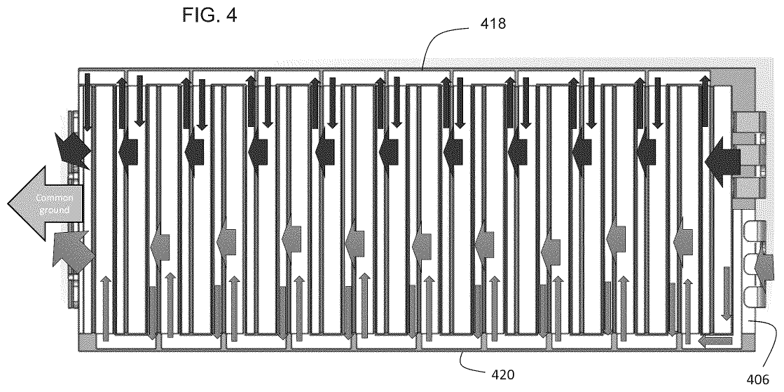

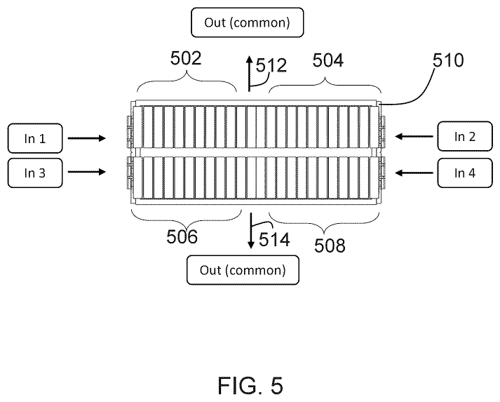

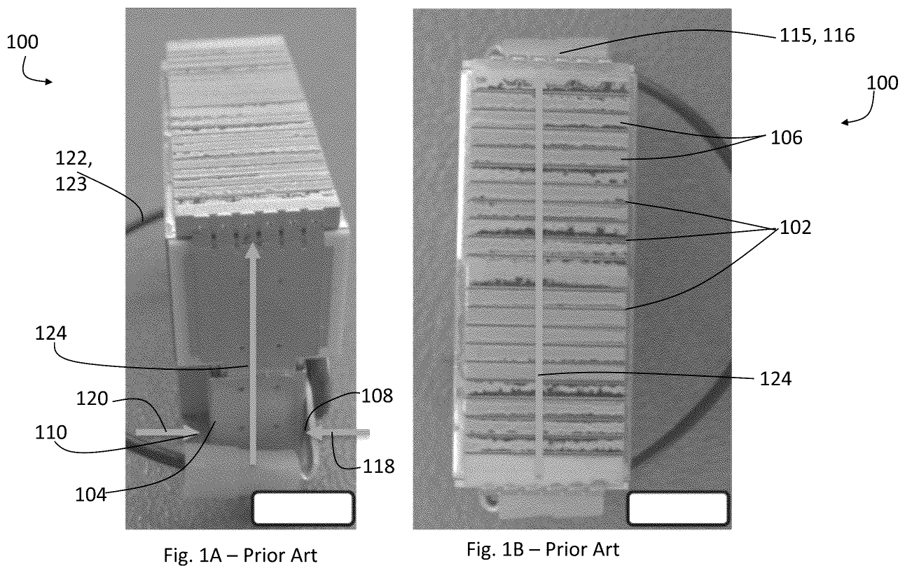

### DETAILED DESCRIPTION

As used herein “laser diode assembly”, “laser diode stack”, “laser diode array”, and “laser bar assembly” are used interchangeably.

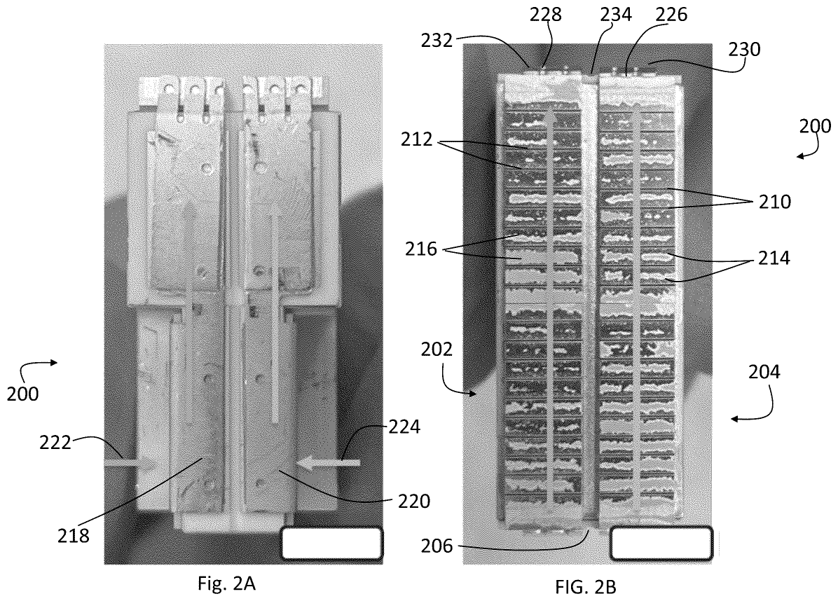

Referring to FIGS. 2A and 2B, there is shown a dual laser diode assembly 200 on a single heatsink in accordance with the present disclosure. Assembly 200 comprises two independent laser bar assemblies 202, 204 on a single heatsink 206. Laser bar assemblies 202, 204 each comprise a plurality of individual laser bars 210, 212, respectively, separated by spacers 214, 216 respectively.

Independent electrical terminals 218, 220 are affixed to one end of laser bar assemblies 202, 204, respectively. Two electrical wires 222, 224 are connected to terminals 218, 220. At the other end of the laser bar assemblies 202, 204, are provided separate terminals 226, 228 to which are connected wires 230, 232, respectively.

Not shown in FIGS. 2A, 2B are the optics that traditionally will be provided with the laser bar assemblies, since the optics per se comprise conventional optics and are not part of the present disclosure. Also not shown are the power supply and the controller, both of which also are conventions.

As can be seen in FIGS. 2A, 2B laser bar assemblies 202, 204 are physically and electrically insulated from one another by an air space 234.

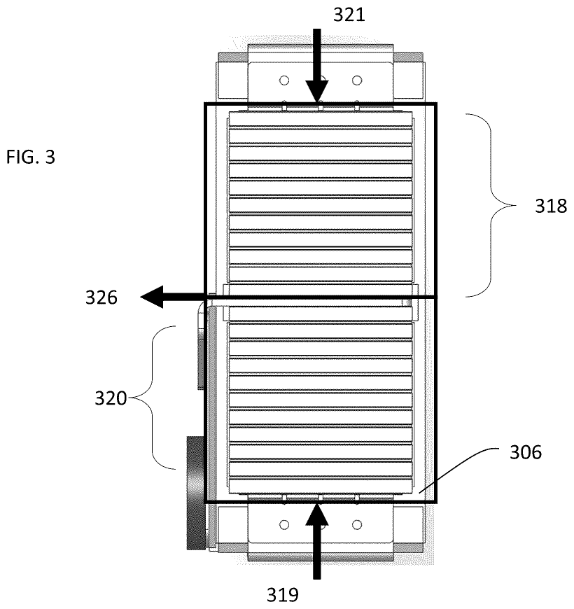

Referring to FIG. 3, in another embodiment in another assembly the two stacks or layer bar assemblies 318, 320, may be assembled rotated to one another on a common heatsink 306, and connected to one another at a common cathode or negative side 326. With this arrangement positive connections 319, 321 are arranged at opposite ends of the two stacks 318, 320.

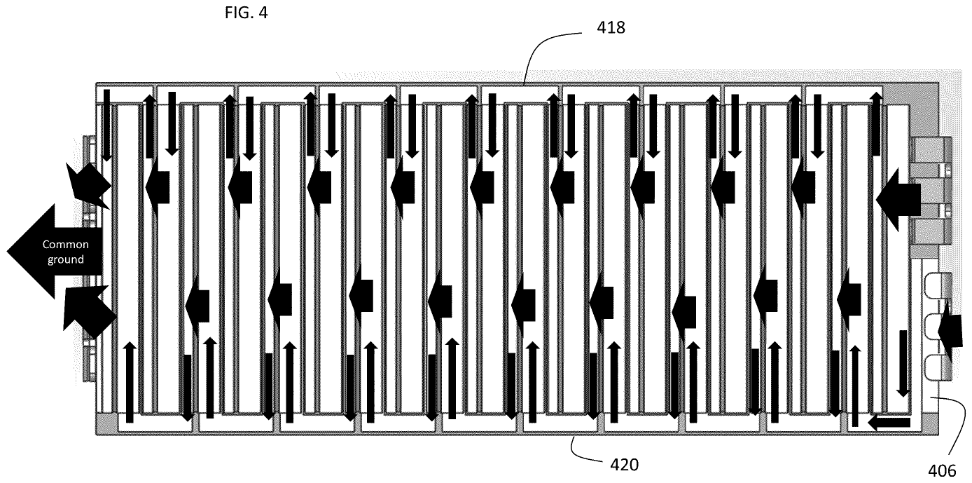

Referring to FIG. 4, in still yet another embodiment two laser bar assemblies 418, 420 are interleaved with another on a common heatsink 406. To form this embodiment we can, for example, metalize a ceramic base and the metallization in the ceramic could be used to make contacts for the laser bars. Patterned in this way that we would be able to operate one stack at a time since they are electrically isolated from one another.

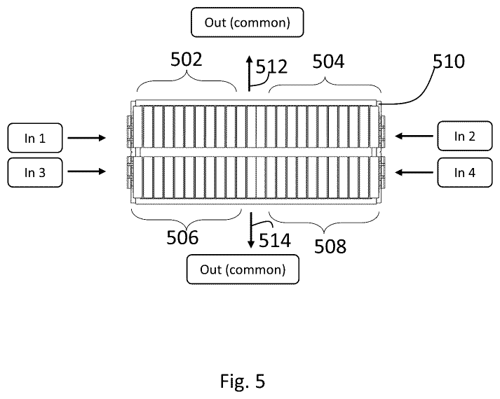

FIG. 5 illustrates still yet another embodiment in which four laser bar assemblies 502, 504, 506, 508 are assembled on a common heatsink 510. This embodiment essentially combines two rows of laser bar assemblies 502, 504 and 506, 508 spaced from one another on common heatsink 510, and which laser bar assemblies 502 and 504 on the one hand, and laser bar assemblies 506 and 508, on the other hand are rotated and connected to one another at common cathode 512, 514, respectively, i.e., similar to the FIG. 3 embodiment.

In accordance with the present disclosure we essentially split a conventional laser bar assembly into two laser bar assemblies, each having separate electrical paths. Thus, we essentially have two laser assemblies on a single heatsink in the same package. One terminal or electrode 218 is on one side of one of the laser bar assembly 202, and a separate terminal 220 is provided on the opposite side of the other laser bar assembly 204. And in like matter, the second terminal or electrode connections 230, 232 for the two laser bar assemblies 202, 204 are provided at the other ends of the laser bar assembly 202, 204, respectively.

Providing two laser bar or stack assemblies on a single heatsink provides many advantages. For one, this permits us to produce a far more compact laser assembly. Also, having two laser bar or stack assemblies on a single heatsink in a single package provides multiple operating modes. The individual laser bar or stack assemblies may be operated independently. Thus, for certain applications, we may be able to run one electrode assembly or the other where half the power is required.

The individual electrode laser bar assemblies also may be operated in pulse mode. Thus, it is possible to operate each laser bar assembly independently so that they operate in pulse modes and different frequencies.

In yet another embodiment, we can operate the two laser bar assemblies at different pulse timings or pulse lengths. This permits us to custom tailor each laser bar assembly to whatever the user may need.

In still yet another embodiment, we could operate the laser bar assemblies out of mode with one another. Thus, one laser bar assembly could be on while the other is off. This permits us to better manage heat loads. Also, by operating the laser bar assemblies separately we could drive the individual laser assemblies to higher power or energy levels without over stressing the laser diode or heatsink.

In still yet another embodiment, we could operate the individual laser bar assemblies at different wavelengths. Operating at different wavelengths would be particularly useful for medical, industrial, and defense applications.

In still yet another embodiment, we can increase the number of laser bars in one array relative to the other.

In yet another embodiment, we could connect the two laser bar assemblies in series by configuring the terminal or electrode connections.

In still yet another embodiment, the laser assembly could have beam conditioning through use of optics.

In yet another embodiment, we could employ different optics on each laser bar assembly. As a result, we could change optical characteristics of the assembly by switching between laser bar assemblies.

In still another embodiment, we can offset one stack verses the other so that there is a gap between certain laser bars. With such arrangement we could alternate back and forth between the individual laser diode bar assemblies, whereby to increase light fill factor and emission uniformity.

Still other changes are possible.

It should be emphasized that the above-described embodiments of the present disclosure, particularly, any “preferred” embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed:

1. A laser assembly comprising multiple laser diode assemblies including a first laser diode assembly and a second laser diode assembly, wherein the first laser diode assembly and the second diode assembly are configured to be operated independently or simultaneously and are assembled on a single heatsink.

2. The laser assembly of claim 1, wherein the first laser diode assembly and a second laser diode assembly each contain a same number of laser bars, or contain a different number of bars.

3. The laser assembly of claim 1, wherein the first laser diode assembly and the second laser diode assembly are configured to run simultaneously.

4. The laser assembly of claim 1, wherein the first laser diode assembly and the second laser diode assembly are configured to run independently of one another.

5. The laser assembly of claim 1, wherein the first laser diode assembly and the second laser diode assembly are configured to run in pulse mode, or in a constant current mode.

6. The laser assembly of claim 5, wherein the first laser diode assembly and the second laser diode assembly are configured to run in phase.

7. The laser assembly of claim 5, wherein the first laser diode assembly and the second laser diode assembly are configured to run out of phase.

8. The laser assembly of claim 1, wherein the first laser diode assembly and the second laser diode assembly are connected in series.

9. The laser assembly of claim 1, wherein the first laser diode assembly and the second laser diode assembly are connected in parallel.

10. The laser assembly of claim 1, wherein the first laser diode assembly and the second laser diode assembly have different emission spectrums.

11. The laser assembly of claim 1, wherein the first laser diode assembly and the second laser diode assembly have laser diode bars of different dimensions.

12. The laser assembly of claim 1, wherein the first laser diode assembly and the second laser diode assembly have laser diode bars that have different operating characteristics.

13. The laser assembly of claim 1, wherein the first laser diode assembly and the second laser diode assembly have different dimensions.

14. The laser assembly of claim 1, wherein the first laser diode assembly and the second laser diode assembly are interleaved with one another.

15. The laser assembly of claim 1, wherein the first laser diode assembly and the second laser diode assembly are rotated to one another, and share a common electrode.

16. The laser assembly of claim 15, wherein the first laser assembly and the second laser assembly share a common cathode.

17. The laser assembly of claim 1, further comprising optics configured for conditioning a beam generated by the laser assembly.
